(19) United States
(12) Patent Application Publication
(10) Pub. No.: US 2019/0177841 A1
(43) Pub. Date: Jun. 13, 2019

(54) FILM FORMING APPARATUS

(71) Applicant: SAMSUNG ELECTRONICS CO., LTD., Suwon-si (KR)

(72) Inventors: Kazuyuki TOMIZAWA, Yokohama (JP); Masashi KIKUCHI, Yokohama (JP); Michio ISHIKAWA, Yokohama (JP); Naoki TAKAHASHI, Yokohama (KR)

(21) Appl. No.: 15/847,392

(22) Filed: Dec. 19, 2017

(30) Foreign Application Priority Data
Dec. 7, 2017 (KR) 10-2017-0167221

(51) Int. Cl. C23C 16/458; C23C 16/52; C23C 16/46; H01L 21/683; H01L 21/687

(52) U.S. Cl. CPC C23C 16/4586; C23C 16/52; C23C 16/463; H01L 21/68785; C23C 16/4581; H01L 21/6833; H01L 21/68764; C23C 16/4584

(57) ABSTRACT

Provided is a film forming apparatus that can be used for an ultrahigh temperature film forming process. A film forming apparatus for forming a film on a wafer in a chamber may include a rotary stage configured to rotate in a circumferential direction, the rotary stage having a loading surface, on which the wafer may be loaded, a heater provided in the rotary stage to heat the wafer loaded on the loading surface, and a power supply part configured to supply electric power to the heater. The rotary stage includes a rotary shaft, which may be provided to penetrate the chamber and may be supported to be rotatable, the power supply part may be electrically coupled to the heater and may have a wire, which may be extended to an outside of the chamber through a penetration hole penetrating the rotary shaft in an axis direction, the heater may be configured to heat the wafer loaded on the loading surface of the rotary stage, to a temperature of 600° C. to 2000° C., and the rotary shaft may be formed of ceramics or glass having a heat-resistant property under the temperature.

### CROSS-REFERENCE TO RELATED APPLICATION

Korean Patent Application No. 10-2017-0167221, filed on Dec. 7, 2017, in the Korean Intellectual Property Office, and entitled: “Film Forming Apparatus,” is incorporated by reference herein in its entirety.

### BACKGROUND OF THE INVENTION

The present disclosure relates to a film forming apparatus.

In an apparatus for forming a film on a semiconductor wafer (hereinafter simply called ‘wafer’), a chemical vapor deposition (CVD) method or an epitaxial growth method is used to form a thin film on a surface of the wafer during heating the wafer provided in a decompressive chamber (i.e., a film formation room).

Furthermore, in the film forming process, the film forming apparatus is configured to irradiate the wafer in the chamber with infrared light, which is emitted from an infrared light lamp placed outside the chamber. The infrared light may be incident into the chamber through a window, which is formed of glass (e.g., quartz) having high transmittance to infrared light. The wafer is indirectly heated through this process.

However, in such an indirect wafer-heating method, by-products to be produced in the chamber are deposited on the window to cause a change in transmittance of the infrared light and consequently a variation in heating temperature of a wafer. In addition, due to an in-plane variation in temperature of a wafer, there is a difficulty in stably and uniformly forming a film. Thus, there is a method of placing a heater configured to indirectly heat a wafer, in the chamber.

In a film forming apparatus using a CVD method, a film forming speed or a film property may be dependent on a gas flow, and thus, in order to improve the uniformity in thickness or physical/chemical characteristics of the film, the wafer is rotated in an in-plane rotation during the film forming process. For this, the film forming apparatus includes a rotary stage, a heater, and an apparatus (e.g., a wafer loading apparatus), which is called a susceptor (e.g., see Patent Document 1). The rotary stage has a loading surface, on which a wafer is loaded, and is configured to rotate in a circumferential direction. The heater is provided in the rotary stage and is configured to heat a wafer loaded on the loading surface. The wafer loading apparatus includes an electrostatic chuck, which is configured to chuck the wafer loaded on the loading surface.

However, since a silicon (Si) substrate usually used as the wafer is lightweight, its position on the loading surface may be changed by a small vibration or gas flow during its rotation. A change in position of the wafer on the loading surface may lead to production of particles or a process error in a step of delivering the wafer. Thus, an electrostatic chuck, which is used in a sputtering system or an etching system, is used to chuck the wafer loaded on the loading surface, and this makes it possible to stably maintain a rotating wafer in the film forming process.

In the meantime, to indirectly heat the wafer using the radiation from the heater, it is necessary to set a heating temperature by the heater to a temperature higher than a desired heating temperature. However, in a film forming apparatus using a CVD method, a process gas is thermally decomposed to form a film, and thus, the heater, whose temperature should be maintained to be higher than that of the wafer, may cause an increase in amount of decomposition products. This may result in an undesired particle production, and thus, a gas cleaning step should be frequently performed, which may lead to deterioration in productivity.

In addition, since the wafer loaded on the loading surface is heated by the radiation from the stage, the heater, the stage, and the wafer have high heating temperatures in enumerated order. Thus, in order to heat the wafer to the temperature necessary for the film forming process, it is necessary to set the heating temperature of the heater to a higher value.

To overcome such issues, a plurality of heater coils (e.g., heating resistors) are placed in a stage to allow the wafer to be heated by a heater located near the same. For all that, in a conventional film forming process using a CVD method, a wafer needs to be heated to 600° C. or higher. In this case, since wires electrically coupled to the heater or the electrostatic chuck are exposed to high temperature environment, it is very difficult to normally operate the heater or the electrostatic chuck.

### PRIOR ART DOCUMENT

### Patent Document

[Patent Document 1] Japanese Patent Application Publication No. 2011-233929

### SUMMARY

Some embodiments of the inventive concept provide a film forming apparatus that can be used for an ultrahigh temperature film forming process.

According to some embodiments of the inventive concept, a film forming apparatus may be configured to form a film on a wafer in a chamber. The apparatus may include a rotary stage configured to rotate in a circumferential direction and have a loading surface, on which the wafer is loaded, a heater provided in the rotary stage to heat the wafer loaded on the loading surface, and a power supply part configured to supply electric power to the heater. The rotary stage may include a rotary shaft, which is provided to penetrate the chamber and is supported to be rotatable, and the power supply part may be electrically coupled to the heater and may have a wire, which is extended to an outside of the chamber through a penetration hole penetrating the rotary shaft in an axis direction. The heater may be configured to heat the wafer loaded on the loading surface of the rotary stage to a temperature of 600° C. to 2000° C., and the rotary shaft may be formed of ceramics or glass having heat-resistant and corrosion-resistant properties under the temperature.

In some embodiments, the ceramics may include silicon nitride.

In some embodiments, the glass may include quartz glass.

In some embodiments, the apparatus may further include a cooling device that is provided outside the chamber and is used to cool down the rotary shaft.

In some embodiments, the apparatus may further include an electrostatic chuck, which is provided in the rotary stage and is configured to chuck the wafer loaded on the loading surface. The power supply part may include a wire, which is electrically coupled to the electrostatic chuck and is extended to an outside of the chamber through a penetration hole penetrating the rotary shaft in an axis direction. The power supply part may supply electric power to the electrostatic chuck through the wire.

In some embodiments, the apparatus may further include a temperature measurement unit provided in the rotary stage to measure a temperature of the wafer loaded on the loading surface of the rotary stage. The temperature measurement unit may include a thermocouple electrically coupled to a wire, which is extended to an outside of the chamber through a penetration hole penetrating the rotary shaft in an axis direction.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a sectional view schematically illustrating a structure of a film forming apparatus, according to some embodiments of the inventive concept.

FIG. 2 is a sectional view of a rotary shaft, taken along line X-X′ of FIG. 1.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown.

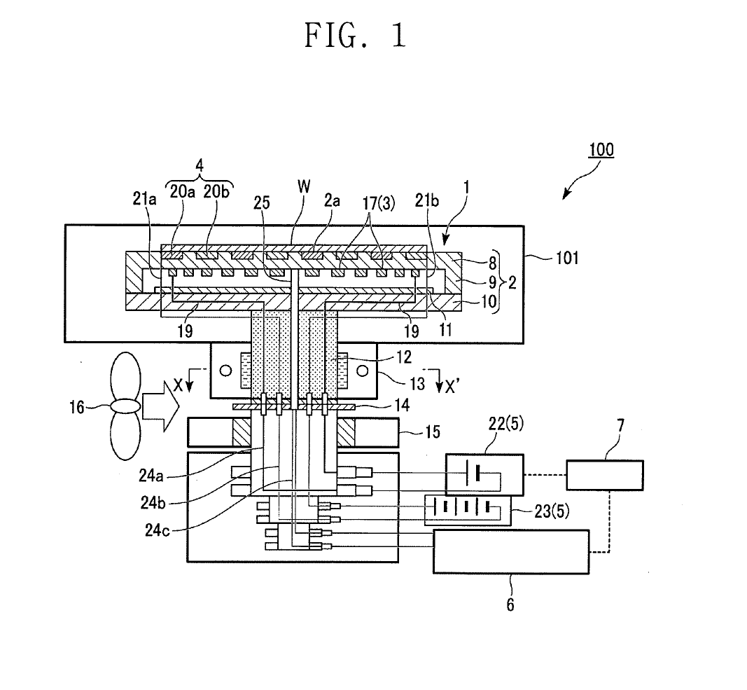

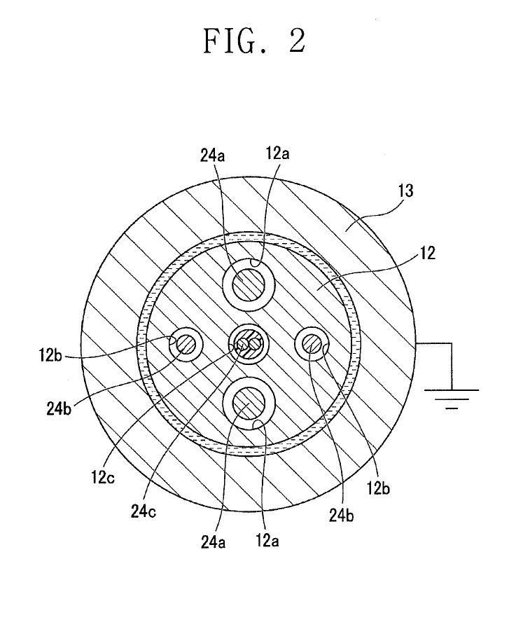

As an embodiment of the inventive concept, a film forming apparatus 100 including a susceptor 1 shown in FIGS. 1 and 2 will be described below. Here, FIG. 1 is a sectional view schematically illustrating a structure of the film forming apparatus 100 including the susceptor 1. FIG. 2 is a sectional view of a rotary shaft 12, taken along line X-X′ of FIG. 1.

According to some embodiments of the inventive concept, the film forming apparatus 100 may be configured to forming a film on a semiconductor wafer W (hereinafter simply called ‘wafer’) using for example chemical vapor deposition (CVD) method or epitaxial growth method. For example, the film forming apparatus 100 may be used to form a thin film on a surface of the wafer W.

In some embodiments, the film forming apparatus 100 may include a chamber 101, whose internal pressure can be lowered, and a susceptor 1 (i.e., a wafer loading apparatus), which is provided in the chamber 101. The susceptor 1 may include a rotary stage 2, which is configured to load the wafer W thereon, a heater 3, which is configured to heat the wafer W loaded on a loading surface 2a of the rotary stage 2, an electrostatic chuck 4, which is configured to chuck the wafer W loaded on the loading surface 2a of the rotary stage 2, a power supply part 5, which is configured to supply electric power to the heater 3 and the electrostatic chuck 4, a temperature measurement unit 6, which is configured to measure temperature of the wafer W loaded on the loading surface 2a of the rotary stage 2, and a power control unit 7, which is configured to control the electric power to be supplied from the power supply part 5 to the heater 3, based on temperature data measured by the temperature measurement unit 6.

The rotary stage 2 may include a top plate 8, which is shaped like a circular plate and serves as the loading surface 2a, a side skirt 9, which is shaped like a hollow cylinder extending from an edge of the top plate 8 in an opposite (i.e., downward) direction of the loading surface 2a, and a bottom plate 10, which is shaped like a circular plate closing an opposite side or bottom surface of the side skirt 9 opposite to the top plate 8.

Each of the top plate 8, the side skirt 9, and the bottom plate 10 may be formed of or include at least one of insulating materials having excellent heat-resistant and corrosion-resistant properties (e.g., alumina ceramics, aluminum nitride ceramics, carbon-based ceramics, quartz, and so forth). In some embodiments, the top plate 8 and the side skirt 9 may be provided in the form of a single body and may be formed of graphite (i.e., one of carbon-based ceramics), whereas the bottom plate 10 may be formed of quartz. Furthermore, a thermal insulator 11, which is formed of quartz and so forth and is shaped like a circular plate, may be provided on a surface of the bottom plate 10.

In certain embodiments, the side skirt 9 and the bottom plate 10 may not be provided in the form of the single body and may be separately formed. In addition, the shape of the side skirt 9 may not be limited to the afore-described cylindrical shape. For example, the side skirt 9 may be provided to have a downwardly increasing diameter, i.e., a tapered shape.

The rotary stage 2 may have a rotary shaft 12, which is shaped like a hollow cylinder and in which a plurality of penetration holes 12a, 12b, and 12c are formed, and here, the penetration holes 12a, 12b, and 12c may be formed to penetrate the rotary shaft 12 in an axis direction of the rotary shaft 12. The rotary shaft 12 may be provided to protrude downwardly from a center region of a bottom surface of the bottom plate 10 and to penetrate the chamber 101. Here, the rotary shaft 12 may be supported by a rotary vacuum seal 13, which is placed on a bottom surface of the chamber 101, and may be configured to be rotatable. In some embodiments, a magnetic fluid seal may be used as the rotary vacuum seal 13. In addition, the rotary shaft 12 may be coupled to a driving motor 15 through a vacuum flange 14, which is provided below the rotary shaft 12 or between the rotary shaft 12 and the driving motor 15. The vacuum flange 14 may be formed of an insulating material (e.g., ceramics). Due to the afore-described configuration, if the driving motor 15 rotates the rotary shaft 12 in the film forming process, the rotary stage 2 may also rotate in its circumferential direction.

In the film forming process, the wafer W loaded on the loading surface 2a of the rotary stage 2 may be heated up to a temperature of 600° C. to 2000° C. by the heater 3. The rotary shaft 12 may be configured in such a way that it is not damaged under such high temperature environment and is not corroded by reactive gas, such as H₂, HCl, and Cl₂. For example, the rotary shaft 12 may be formed of or include at least one of insulating materials (e.g., ceramics or glass) having excellent heat-resistant and corrosion-resistant properties. In some embodiments, the glass may include a quartz (SiO₂) glass or a sapphire (Al₂O₃) glass. The ceramics may include oxide ceramics (e.g., alumina (Al₂O₃), zirconium oxide (ZrO₂), and so forth) and non-oxide ceramics (e.g., aluminum nitride (AlN), silicon nitride (Si₃N₄), silicon carbide (SiC), boron nitride (BN), carbon ceramics, and so forth).

In some embodiments, quartz or silicon nitride may be mainly used for the rotary shaft 12. For example, the rotary shaft 12 may be formed of silicon nitride.

In addition, a cooling device 16 may be provided outside the chamber 101 and may be used to cool down the rotary shaft 12. The cooling device 16 may be a cooling fan, which is provided below the chamber 101 and is configured to supply the air toward the rotary shaft 12 in the film forming process. However, the cooling device 16 may not be limited to an air-cooled cooling device such as the above cooling fan, and for example, it may be a water-cooled cooling device. In certain embodiments, a cooling device such as a Piezoelectric device or a Peltier device may be used as the cooling device 16.

The heater 3 may include a plurality of heater coils 17, which are provided on a bottom or inner surface of the top plate 8, and a plurality of electrode portions 19, which are arranged side-by-side along an internal circumferential surface of the side skirt 9.

The plurality of heater coils 17 may be concentric or spiral heating resistors, which are arranged side-by-side with a predetermined space in a diameter direction of the top plate 8. The heating resistors constituting the heater coils 17 may be formed of a highly heat-resistant carbon-containing conductive material (e.g., a CVD boron nitride (PBN) thin film or a pyrolysis graphite (PG) thin film). In addition, the heating resistors may be formed of a low resistance carbon material (e.g., having volume resistivity of 4.8 μΩm to 11 μΩm).

The plurality of the electrode portions 19 may be electrically coupled to the plurality of the heater coils 17 and may be arranged side-by-side with a predetermined space in a circumferential direction of the side skirt 9. In addition, each of the electrode portions 19 may be extended toward the rotary shaft 12.

In the film forming process, electric power may be supplied to the plurality of the heater coils 17 through the plurality of the electrode portions 19. The electric power may be used to heat the heater coils 17 and consequently to heat the wafer W loaded on the loading surface 2a.

The electrostatic chuck 4 may include a pair of inner electrodes 20a and 20b, which are buried in a dielectric layer near a surface (e.g., the loading surface 2a) of the top plate 8, and a pair of electrode portions 21a and 21b, which are electrically coupled to the pair of inner electrodes 20a and 20b and are extended toward the rotary shaft 12.

In the film forming process, a voltage may be applied between the pair of inner electrodes 20a and 20b through the pair of electrode portions 21a and 21b. In this case, a reverse voltage may be induced on the surface of the wafer W, and thus, the wafer W may be chucked by Coulomb force, Johnsen-Rahbek force, or gradient force therebetween.

The power supply part 5 may include a heater power 22, which is configured to supply the electric power to the heater 3, and an electrostatic chuck power 23, which is configured to supply the electric power to the electrostatic chuck 4. The heater power 22 may be electrically coupled to the heater 3 (e.g., the plurality of the electrode portions 19) through a plurality of first wires 24a, which are extended to the outside of the chamber 101 through the penetration hole 12a of the rotary shaft 12. The electrostatic chuck power 23 may be electrically coupled to the electrostatic chuck 4 (in detail, the pair of electrode portions 21a and 21b) through a pair of second wires 24b, which are extended to the outside of the chamber 101 through the penetration hole 12b of the rotary shaft 12.

A pair of third wires 24c may be extended to the outside of the chamber 101 through the penetration hole 12c of the rotary shaft 12, and the temperature measurement unit 6 may include a thermocouple 25 electrically coupled to the pair of third wires 24c. The thermocouple 25 may be extended through the penetration hole 12c of the rotary shaft 12 to be in contact with the top plate 8. The temperature measurement unit 6 may be configured to measure a temperature (e.g., in the form of small signals) of the wafer W, which is loaded on the loading surface 2a, using the thermocouple 25, and then to provide the measurement results to the power control unit 7.

Based on the temperature data measured by the temperature measurement unit 6, the power control unit 7 may control the electric power to be supplied from the heater power 22 to the heater 3, until the wafer W has a desired temperature.

As described above, in the film forming apparatus 100 according to the present embodiment, an insulating material having excellent heat-resistant and corrosion-resistant properties is used for the rotary shaft 12, and thus, it may be possible to protect the wires 24a, 24b, and 24c, which are provided to pass through the penetration holes 12a, 12b, and 12c of the rotary shaft 12, from thermal damage, even when the rotary shaft 12 is heated to a high temperature of 600° C. to 2000° C. by the heater 3 in the film forming process. Furthermore, it may be possible to electrically separate each of the wires 24a, 24b, and 24c from the rotary shaft 12. In addition, it may be possible to prevent the wires 24a, 24b, and 24c from being corroded by a process gas to be used in the film forming process.

Thus, in the film forming apparatus 100 according to the present embodiment, it may be possible to normally operate the heater 3, the electrostatic chuck 4, and the thermocouple 25, while preventing the wires 24a, 24b, and 24c, which are electrically and respectively coupled to the heater 3, the electrostatic chuck 4, and the thermocouple 25, from being exposed to high temperature environment. This may make it possible to realize an ultrahigh temperature film forming process.

As described above, according to some embodiments of the inventive concept, it may be possible to provide a film forming apparatus that can be used for an ultrahigh temperature film forming process.

While example embodiments of the inventive concepts have been particularly shown and described, it will be understood by one of ordinary skill in the art that variations in form and detail may be made therein without departing from the spirit and scope of the attached claims.

1. A film forming apparatus for forming a film on a wafer in a chamber, comprising:
a rotary stage configured to rotate in a circumferential direction, the rotary stage having a loading surface, on which the wafer is loaded;
a heater provided in the rotary stage to heat the wafer loaded on the loading surface; and
a power supply part configured to supply electric power to the heater,
wherein:
the rotary stage comprises a rotary shaft, which is provided to penetrate the chamber and is supported to be rotatable,
the rotary shaft comprises a penetration hole penetrating the rotary shaft in an axis direction,
the power supply part comprises a first wire electrically coupled to the heater in the penetration hole, and
the heater is configured to heat the wafer loaded on the loading surface of the rotary stage, to a temperature of 600° C. to 2000° C.

2. The apparatus as claimed in claim 1, wherein the rotary shaft is formed of ceramics that comprise silicon nitride.

3. The apparatus as claimed in claim 1, wherein the rotary shaft is formed of glass that comprises quartz glass.

4. The apparatus as claimed in claim 1, further comprising a cooling device that is provided outside the chamber and is used to cool down the rotary shaft.

5. The apparatus as claimed in claim 1, further comprising an electrostatic chuck, which is provided in the rotary stage and is configured to chuck the wafer loaded on the loading surface,
wherein the power supply part comprises a second wire, which is electrically coupled to the electrostatic chuck and is extended to an outside of the chamber through a penetration hole penetrating the rotary shaft in an axis direction, and
the power supply part supplies electric power to the electrostatic chuck through the second wire.

6. The apparatus as claimed in claim 1, further comprising a temperature measurement unit provided in the rotary stage to measure a temperature of the wafer loaded on the loading surface of the rotary stage,
wherein the temperature measurement unit comprises a thermocouple electrically coupled to a third wire, which is extended to an outside of the chamber through a penetration hole penetrating the rotary shaft in an axis direction.

7. The apparatus as claimed in claim 1, wherein:
the power supply part comprises a second wire, which is electrically coupled to the electrostatic chuck and is extended to an outside of the chamber through a penetration hole penetrating the rotary shaft in an axis direction,
the temperature measurement unit comprises a third wire, which is electrically coupled to a thermocouple and is extended to an outside of the chamber through a penetration hole penetrating the rotary shaft in an axis direction, and
the third wire is more adjacent to the axis of the rotary shaft than the first wire and second wire.
